(19) United States
(12) Patent Application Publication
(10) Pub. No.: US 2024/0224513 A1
(43) Pub. Date: Jul. 4, 2024

(54) SEMICONDUCTOR DEVICE AND MANUFACTURING METHOD OF THE SEMICONDUCTOR DEVICE

(71) Applicant: SK hynix Inc., Icheon-si Gyeonggi-do (KR)

(72) Inventors: Jong Hun KIM, Icheon-si Gyeonggi-do (KR); Sang Hyuk NAM, Icheon-si Gyeonggi-do (KR); Byung Wook BAE, Icheon-si Gyeonggi-do (KR); Sang Bum LEE, Icheon-si Gyeonggi-do (KR); Sang Hyon KWAK, Icheon-si Gyeonggi-do (KR)

(73) Assignee: SK hynix Inc., Icheon-si Gyeonggi-do (KR)

(21) Appl. No.: 18/328,615

(22) Filed: Jun. 2, 2023

(30) Foreign Application Priority Data
Dec. 28, 2022 (KR) 10-2022-0186591

(51) Int. Cl. H10B 41/27; H10B 41/10; H10B 43/10; H10B 43/27

(52) U.S. Cl. CPC H10B 41/27; H10B 41/10; H10B 43/10; H10B 43/27

(57) ABSTRACT

A semiconductor device includes a first gate structure including first interlayer dielectric layers and first gate lines that are alternately stacked. The semiconductor device also includes a plurality of first supports passing through the first gate structure. The semiconductor device further includes a second gate structure including second interlayer dielectric layers and second gate lines that are alternately stacked. The semiconductor device additionally includes a plurality of second supports passing through the second gate structure. The semiconductor device moreover includes an isolation structure disposed between the first gate structure and the second gate structure, the isolation structure including one or more first protrusions protruding between the first supports and one or more second protrusions protruding between the second supports.

### CROSS-REFERENCE TO RELATED APPLICATION

This application claims priority under 35 U.S.C. § 119(a) to Korean Patent Application No. 10-2022-0186591 filed on Dec. 28, 2022, in the Korean Intellectual Property Office, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is mainly determined by an area occupied by a unit memory cell. Recently, as improvement in the degree of integration of a semiconductor device for forming memory cells in a single layer on a substrate reaches a limit, a three-dimensional semiconductor device for stacking memory cells on a substrate has been proposed. Furthermore, to improve the operational reliability of such a semiconductor device, various structures and manufacturing methods have been developed.

### SUMMARY

In an embodiment, a semiconductor device may include: a first gate structure including first interlayer dielectric layers and first gate lines that are alternately stacked; a plurality of first supports passing through the first gate structure; a second gate structure including second interlayer dielectric layers and second gate lines that are alternately stacked; a plurality of second supports passing through the second gate structure; and an isolation structure disposed between the first gate structure and the second gate structure, the isolation structure including one or more first protrusions protruding between the first supports and one or more second protrusions protruding between the second supports.

In an embodiment, a semiconductor device may include: a first gate structure including a first cell region and a first contact region; a second gate structure including a second cell region and a second contact region; an isolation structure disposed between the first gate structure and the second gate structure, the isolation structure including a first protrusion protruding toward the first gate structure and a second protrusion protruding toward the second gate structure; a first support passing through the first contact region; and a second support passing through the second contact region, the second support arranged asymmetrically with the first support with the isolation structure interposed between the second support and the first support.

In an embodiment, a manufacturing method of a semiconductor device may include: forming a stack structure including first material layers and second material layers that are alternately stacked; forming a trench separating the stack structure into a first stack structure and a second stack structure, the trench including a protrusion; forming a first opening passing through the first stack structure; forming a second opening passing through the second stack structure; forming an isolation structure in the trench; and forming supports in the first opening and the second opening.

In an embodiment, a manufacturing method of a semiconductor device may include: forming a stack structure including a cell region and a contact region; forming channel structures passing through the cell region of the stack structure; forming supports passing through the contact region of the stack structure; and forming an isolation structure passing through the contact region of the stack structure, the isolation structure including protrusions protruding between the supports.

### BRIEF DESCRIPTION OF THE DRAWINGS

FIG. 1A to FIG. 1C are diagrams for describing the structure of a semiconductor device in accordance with an embodiment.

FIG. 2A to FIG. 2C are cross-sectional views illustrating the structure of a semiconductor device in accordance with an embodiment.

FIG. 3 is a diagram for describing the structure of a semiconductor device in accordance with an embodiment.

FIG. 4A and FIG. 4B are diagrams illustrating the structure of a semiconductor device in accordance with an embodiment.

FIGS. 5A, 6A, 7A, 8A, 9A, 10A, and 11A and FIGS. 5B, 6B, 7B, 8B, 9B, 10B, and 11B are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical spirit of the present disclosure will be described with reference to the accompanying drawings.

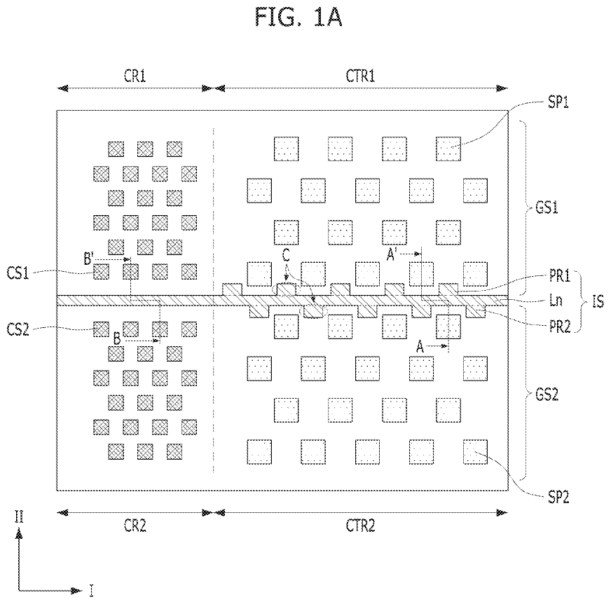

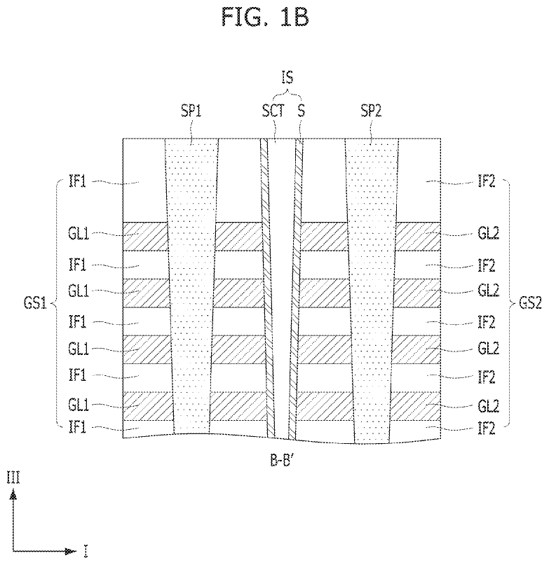

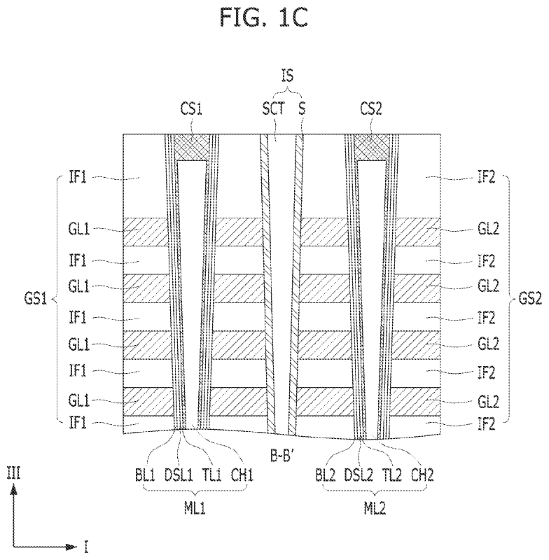

FIG. 1A to FIG. 1C are diagrams for describing the structure of a semiconductor device in accordance with an embodiment. FIG. 1A may be a plan view, FIG. 1B may be a cross-sectional view taken along line A-A′ in FIG. 1A, and FIG. 1C may be a cross-sectional view taken along line B-B′ in FIG. 1A.

Referring to FIG. 1A to FIG. 1C, the semiconductor device may include a first gate structure GS1, a second gate structure GS2, an isolation structure IS, first supports SP1, and second supports SP2. The semiconductor device may further include at least one of first channel structures CS1 and second channel structures CS2.

The first gate structure GS1 may include first gate lines GL1 and first interlayer dielectric layers IF1 that are alternately stacked. The first gate lines GL1 may be gate electrodes of memory cells, select transistors, or the like. As an example, at least one uppermost first gate line GL1 and at least one lowermost first gate line GL1 among the first gate lines GL1 may be select lines, and the remaining first gate lines GL1 may be word lines. The first gate lines GL1 may each include a conductive material such as polysilicon, tungsten, molybdenum, or metal. The first interlayer dielectric layers IF1 may be used to insulate the stacked first gate lines GL1 from each other. The first interlayer dielectric layers IF1 may each include an insulating material such as an oxide, a nitride, or an air gap.

A first cell region CR1 and a first contact region CTR1 may be defined in the first gate structure GS1. The first cell region CR1 may be a region where stacked first memory cells are located. The first contact region CTR1 may be a region where an interconnection structure for driving the stacked first memory cells is located. The first cell region CR1 and the first contact region CTR1 may be adjacent to each other in a first direction I. As an example, the first gate structure GS1 may include at least one first step structure located in the first contact region CTR1. The first step structure may be used to expose each of the first gate lines GL1. The semiconductor device may also include first contact plugs respectively connected to the first gate lines GL1 exposed through the first step structure.

The second gate structure GS2 may include second gate lines GL2 and second interlayer dielectric layers IF2 that are alternately stacked. The second gate lines GL2 may be gate electrodes of memory cells, select transistors, or the like. As an example, at least one uppermost second gate line GL2 and at least one lowermost second gate line GL2 among the second gate lines GL2 may be select lines, and the remaining second gate lines GL2 may be word lines. The second gate lines GL2 may each include a conductive material such as polysilicon, tungsten, molybdenum, or metal. The second interlayer dielectric layers IF2 may be used to insulate the stacked second gate lines GL2 from each other. The second interlayer dielectric layers IF2 may each include an insulating material such as an oxide, a nitride, or an air gap.

A second cell region CR2 and a second contact region CTR2 may be defined in the second gate structure GS2. The second cell region CR2 may be a region where stacked second memory cells are located. The second contact region CTR2 may be a region where an interconnection structure for driving the stacked second memory cells is located. The second cell region CR2 and the second contact region CTR2 may be adjacent to each other in the first direction I. As an example, the second gate structure GS2 may include at least one second step structure located in the second contact region CTR2. The second step structure may be used to expose each of the second gate lines GL2. The semiconductor device may also include second contact plugs respectively connected to the second gate lines GL2 exposed through the second step structure.

The first gate structure GS1 and the second gate structure GS2 may extend in the first direction I. The first gate structure GS1 and the second gate structure GS2 may be adjacent to each other in a second direction II intersecting the first direction I. The first cell region CR1 and the second cell region CR2 may be adjacent to each other in the second direction II, and the first contact region CTR1 and the second contact region CTR2 may be adjacent to each other in the second direction II. The first gate structure GS1 and the second gate structure GS2 may be electrically isolated. As an example, the first gate structure GS1 may belong to a first memory block, and the second gate structure GS2 may belong to a second memory block. The memory block may be a unit of an erase operation.

The first supports SP1 may be used to support the stack structure in a manufacturing process. As an example, the first gate structure GS1 may be formed by replacing sacrificial layers included in the stack structure with the first gate lines GL1, and in the replacement process, the first supports SP1 may support the stack structure. In a plane defined by the first direction I and the second direction II, the first supports SP1 may be arranged in the first direction I, arranged in the second direction II, or arranged in the first direction I and the second direction II. The central axes of the first supports SP1 arranged in one direction may be aligned or offset. The first supports SP1 may pass through the first contact region CTR1 of the first gate structure GS1 in a third direction III. As an example, within the first gate structure GS1, the first supports SP1 may extend in the third direction III. The third direction III may be a direction protruding from the plane defined by the first direction I and the second direction II. As an example, the third direction III may be a stack direction of the first gate lines GL1. The first supports SP1 may each include an oxide, a nitride, a metal, or the like.

The second supports SP2 may be used to support the stack structure in the manufacturing process. As an example, the second gate structure GS2 may be formed by replacing sacrificial layers included in the stack structure with the second gate lines GL2, and in the replacement process, the second supports SP2 may support the stack structure. In the plane defined by the first direction I and the second direction II, the second supports SP2 may be arranged in the first direction I, arranged in the second direction II, or arranged in the first direction I and the second direction II. The central axes of the second supports SP2 arranged in one direction may be aligned or offset. The second supports SP2 may pass through the second contact region CTR2 of the second gate structure GS2 in the third direction III. As an example, within the second gate structure GS2, the second supports SP2 may extend in the third direction III. The second supports SP2 may each include an oxide, a nitride, a metal, or the like.

The first supports SP1 and the second supports SP2 may be asymmetrically arranged. As an example, in the plane defined by the first direction I and the second direction II, the first supports SP1 and the second supports SP2 may be asymmetrically arranged with the isolation structure IS interposed therebetween. The first supports SP1 and the second supports SP2 may also be symmetrically arranged.

The first channel structures CS1 may pass through the first cell region CR1 of the first gate structure GS1. For example, within the first gate structure GS1, the first channel structures CS1 may extend in the third direction III. Through this, a select transistor or a memory cell may be located in a region where the first channel structures CS1 and the first gate lines GL1 intersect each other. The first channel structures CS1 may each include a first memory layer ML1 and a first channel layer CH1. The first memory layer ML1 may include a first blocking layer BL1, a first data storage layer DSL1, or a first tunnel storage layer TL1, or a combination thereof. The first data storage layer DSL1 may include a floating gate, a charge trap material, polysilicon, nitride, a variable resistance material, a phase change material, a nano structure, and the like. The first channel layer CH1 may include a semiconductor material such as silicon (Si), germanium (Ge), polysilicon, or a nano structure.

The second channel structures CS2 may pass through the second cell region CR2 of the second gate structure GS2. For example, within the second gate structure GS2, the second channel structures CS2 may extend in the third direction III. Through this, a select transistor or a memory cell may be located in a region where the second channel structures CS2 and the second gate lines GL2 intersect each other. The second channel structures CS2 may each include a second memory layer ML2 and a second channel layer CH2. The second memory layer ML2 may include a second blocking layer BL2, a second data storage layer DSL2, or a second tunnel storage layer TL2, or a combination thereof. The second data storage layer DSL2 may include a floating gate, a charge trap material, polysilicon, nitride, a variable resistance material, a phase change material, a nanostructure, and the like. The second channel layer CH2 may include a semiconductor material such as silicon (Si), germanium (Ge), polysilicon, or a nano structure.

The first channel structures CS1 and the second channel structures CS2 may be symmetrically arranged. As an example, in the plane defined by the first direction I and the second direction II, the first channel structures CS1 and the second channel structures CS2 may be symmetrically arranged with the isolation structure IS interposed therebetween. The first channel structures CS1 and the second channel structures CS2 may also be asymmetrically arranged. The arrangement method of the supports SP1 and SP2 and the arrangement method of the channel structures CS1 and CS2 may be the same as or different from each other. As an example, the supports SP1 and SP2 may be asymmetrically arranged and the channel structures CS1 and CS2 may be symmetrically arranged, or both the supports SP1 and SP2 and the channel structures CS1 and CS2 may be asymmetrically arranged.

The isolation structure IS may be disposed between the first gate structure GS1 and the second gate structure GS2. The isolation structure IS may be a structure for isolating the first gate structure GS1 and the second gate structure GS2 from each other, and the first gate structure GS1 and the second gate structure GS2 may be electrically isolated by the isolation structure IS. As an example, in the plane defined by the first direction I and the second direction II, the isolation structure IS may extend in the first direction I. In a cross section defined by the first direction I and the third direction III, the isolation structure IS may pass through between the first gate structure GS1 and the second gate structure GS2, and extend in the third direction III. As an example, the isolation structure IS may include a source contact structure SCT and an insulating spacer S. The source contact structure SCT may be electrically connected to a source structure located below the first gate structure GS1 and the second gate structure GS2. The insulating spacer S may surround sidewalls of the source contact structure SCT, and electrically isolate the source contact structure SCT from the first gate lines GL1 and the second gate lines GL2. The isolation structure IS might not include the source contact structure SCT and may be an isolation insulation structure.

The isolation structure IS may include a line part Ln and protrusions PR1 and PR2. The line part Ln may extend in the first direction I on the plane. The line part Ln may pass through between the first gate structure GS1 and the second gate structure GS2 in the cross section, and extend in the third direction III. The protrusions PR1 and PR2 may protrude in the second direction II from sidewalls of the line part Ln. The isolation structure IS may include at least one first protrusion PR1 protruding toward the first gate structure GS1 and at least one second protrusion PR2 protruding toward the second gate structure GS2. As an example, the isolation structure IS may include at least one first protrusion PR1 protruding between the first supports SP1 and at least one second protrusion PR2 protruding between the second supports SP2. The protrusions PR1 and PR2 may each have a circular, elliptical, or polygonal shape in the cross section.

The first protrusions PR1 and the second protrusions PR2 may be arranged in an asymmetrical shape. As an example, the first protrusions PR1 and the second protrusions PR2 may be asymmetrically arranged with respect to the line part Ln in the plane defined by the first direction I and the second direction II. The first protrusions PR1 and the second protrusions PR2 may be symmetrically arranged. Alternatively, the isolation structure IS may have a wavy shape, and the line part Ln may extend in a diagonal direction intersecting the first direction I and the second direction II.

The location, number, shape, and the like of each of the protrusions PR1 and PR2 may be set in consideration of structural stability of the semiconductor device. As an example, the location, number, shape, and the like of each of the protrusions PR1 and PR2 may be set in consideration of bending of the stack structure caused during the manufacturing process. When the isolation structure IS includes only the line part Ln, there is a relatively high possibility that the stack structure is bent between the first supports SP1 or between the second supports SP2 (see region C) during the manufacturing process. Accordingly, the protrusions PR1 and PR2 may be located in the corresponding region C.

According to the structure described above, the isolation structure IS may include the first protrusions PR11, include the second protrusions PR2, or include the first protrusions PR1 and the second protrusions PR2. Accordingly, it is possible to support the stack structure by the protrusions PR1 and PR2 during the manufacturing process, and to reduce, minimize, or prevent bending of the stack structure. By asymmetrically arranging the first supports SP1 and the second supports SP2 and asymmetrically arranging the first protrusions PR1 and the second protrusions PR2, it is possible to reduce, minimize, or prevent an increase in the pitch of a memory block even though the isolation structure IS includes the protrusions PR1 and PR2.

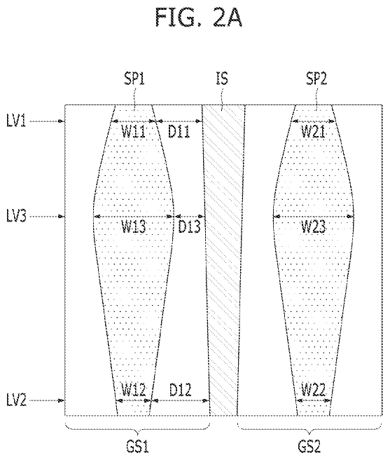

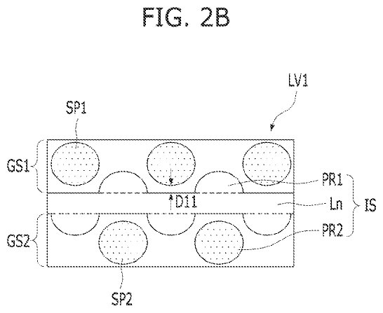

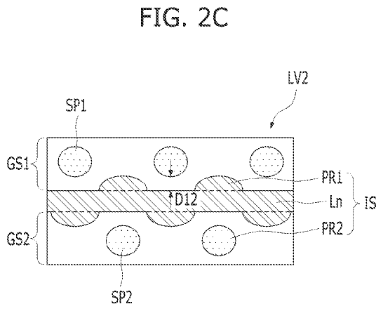

FIG. 2A to FIG. 2C are cross-sectional views illustrating the structure of a semiconductor device in accordance with an embodiment. FIG. 2A may be a cross-sectional view, FIG. 2B may be a plan view of a first level LV1 in FIG. 2A, and FIG. 2C may be a plan view of a second level LV2 in FIG. 2A. Hereinafter, the content overlapping with the previously described content will be omitted.

Referring to FIG. 2A to FIG. 2C, the semiconductor device may include a first gate structure GS1, a second gate structure GS2, a first support SP1, a second support SP2, or an isolation structure IS, or a combination thereof.

The first supports SP1 may each have a substantially uniform width or may have different widths according to levels. As an example, a width W12 of the second level LV2 may be smaller than a width W11 of the first level LV1. The first level LV1 may be an upper part and the second level LV2 may be a lower part. Because the upper part and the lower part may be relative concepts, the first level LV1 may be a lower part and the second level LV2 may be an upper part. The first support SP1 may have a bowing shape. As an example, a third level LV3 may be located between the first level LV1 and the second level LV2, and the first support SP1 may have a maximum width at the third level LV3. A width W13 of the third level LV3 may be greater than the width W11 of the first level and the width W12 of the second level.

The isolation structure IS may be spaced apart from the first support SP1 by a first distance D11. As described above, when the first support SP1 has different widths according to levels, the first distance D11 may also have different values according to levels. The isolation structure IS may be spaced apart from the first support SP1 by the first distance D11 at the first level LV1, by a second distance D12 at the second level LV2, and by a third distance D13 at the third level LV3. The first distance D11 may be greater than the second distance D12, and the third distance D13 may be greater than the first distance D11 and the second distance D12. Accordingly, the first distance D11 may be set in consideration of the bending of the stack structure caused during the manufacturing process, the shape of the first support SP1, and the like. As an example, when the isolation structure IS and the first support SP1 are formed together, the first distance D11 may be set in consideration of the cross-sectional shape, the maximum width, and the like of the first support SP1 so that the isolation structure IS and the first support SP1 may be spaced apart from each other. Similarly, a distance between the isolation structure IS and the second support SP2 may also be set in consideration of the bending of the stack structure, the shape of the second support SP2, and the like.

The isolation structure IS may include the line part Ln, the first protrusions PR1, or the second protrusions PR2, or a combination thereof. The first protrusions PR1 and the second protrusions PR2 may have different sizes according to levels. As an example, the first protrusions PR1 and the second protrusions PR2 may each have a larger area at the first level LV1 than at the second level LV2. The first protrusions PR1 and the second protrusions PR2 may each have a larger area at the third level LV3 than at the first level LV1 and the second level LV2. In the plan view, the first protrusions PR1 and the second protrusions PR2 may each include a curved surface. As an example, the first protrusions PR1 and the second protrusions PR2 may each have a shape such as a circle, an ellipse, or a polygon.

According to the structure described above, the distance D11 between the supports SP1 and SP2 and the isolation structure IS may be set in consideration of the shapes of the supports SP1 and SP2 according to levels. The shapes, sizes, and the like of the first protrusions PR1 and the second protrusions PR2 may be set in consideration of the shapes of the supports SP1 and SP2 according to levels. Accordingly, it is possible to secure the distance between the supports SP1 and SP2 and the isolation structure IS.

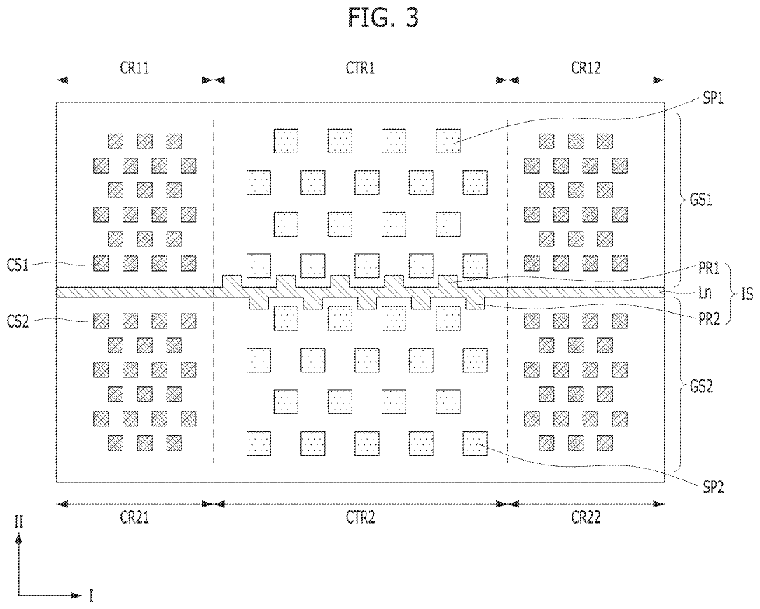

FIG. 3 is a diagram for describing the structure of a semiconductor device in accordance with an embodiment. Hereinafter, the content overlapping with the previously described content will be omitted.

Referring to FIG. 3, the semiconductor device may include a first gate structure GS1, a second gate structure GS2, first supports SP1, second supports SP2, a first channel structure CS1, and a second channel structure CS2, or an isolation structure IS, or a combination thereof.

The first gate structure GS1 may include a pair of first cell regions CR11 and CR12 and a first contact region CTR1. As an example, the first contact region CTR1 may be located between the first cell region CR11 and the first cell region CR12, and the pair of first cell regions CR11 and CR12 may share the contact region CTR1. The second gate structure GS2 may include a pair of second cell regions CR21 and CR22 and a second contact region CTR2. As an example, the second contact region CTR2 may be located between the second cell region CR21 and the second cell region CR22, and the pair of second cell regions CR21 and CR22 may share the contact region CTR2.

The isolation structure IS may be located between the first contact region CTR1 and the second contact region CTR2, and extend between the first cell region CR11 and the second cell region CR21 and between the first cell region CR12 and the second cell region CR22. The isolation structure IS may include first protrusions PR1 protruding between the first supports SP, include second protrusions PR2 protruding between the second supports SP2, or include the first protrusions PR1 and the second protrusions PR2. The first protrusions PR1 and the second protrusions PR2 may each have a shape such as a circle, an ellipse, or a polygon. A line part Ln, the first protrusions PR1, and the second protrusions PR2 may have a wavy shape connected in a curved line.

Although not illustrated in this drawing, the isolation structure IS may also include third protrusions protruding between the first channel structures CS1 or between the second channel structures CS2. By asymmetrically arranging the first channel structures CS1 and the second channel structures CS2, it is possible to reduce, minimize, or prevent an increase in the pitch of a memory block even when the isolation structure IS includes the third protrusions.

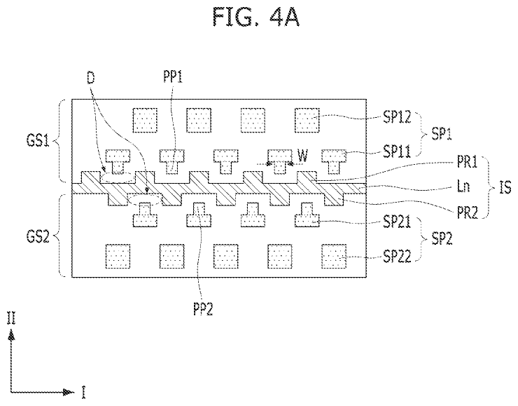

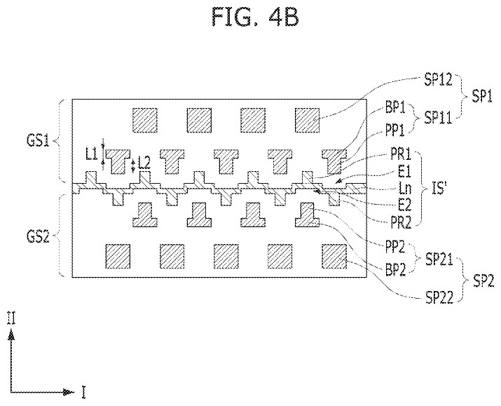

FIG. 4A and FIG. 4B are diagrams illustrating the structure of a semiconductor device in accordance with an embodiment. Hereinafter, the content overlapping with the previously described content will be omitted.

Referring to FIG. 4A, the semiconductor device may include a first gate structure GS1, a second gate structure GS2, first supports SP1, second supports SP2, or an isolation structure IS, or a combination thereof. The isolation structure IS may be located between the first gate structure GS1 and the second gate structure GS2, and the first gate structure GS1 and the second gate structure GS2 may be spaced apart from each other and electrically isolated by the isolation structure IS. The first supports SP1 may be located in a first contact region of the first gate structure GS1, and the second supports SP2 may be located in a second contact region of the second gate structure GS2.

The first supports SP1 may have substantially the same shape or different shapes. When the isolation structure IS includes first protrusions PR1, a sufficient distance might not be secured between the first protrusions PR1 and first supports SP11. Accordingly, the shape of the first supports SP1 may be set in consideration of the distance to the first protrusions PR1. As an example, first supports SP11 located close to the isolation structure IS among the first supports SP1 may include first protruding patterns PP1, respectively, and remaining first supports SP12 might not include the first protrusion pattern PP1. Because the first protrusion pattern PP1 has a relatively narrower width W than remaining regions, a distance between the first support SP11 and the first protrusions PR1 may be secured. Because the first protruding pattern PP1 protrudes between the first protrusions PR1, structural stability of a region D, which is relatively vulnerable to bending, may be supplemented. As an example, in the plane defined by the first direction I and the second direction II, the first supports SP11 may each have a “T” shape.

The second supports SP2 may have substantially the same shape or different shapes. When the isolation structure IS includes second protrusions PR2, a sufficient distance might not be secured between the second protrusions PR2 and second supports SP21. Accordingly, the shape of the second supports SP2 may be set in consideration of the distance to the second protrusions PR2. As an example, second supports SP21 located close to the isolation structure IS among the second supports SP2 may include second protruding patterns PP2, respectively, and remaining second supports SP22 might not include the second protruding pattern PP2. Because the second protruding pattern PP2 has a relatively narrower width W than remaining regions, a distance between the second support SP21 and the second protrusions PR2 may be secured. Because the second protruding pattern PP2 protrudes between the second protrusions PR2, structural stability of the region D, which is relatively vulnerable to bending, may be supplemented. As an example, in the plane defined by the first direction I and the second direction II, the second supports SP21 may each have a “T” shape.

Referring to FIG. 4B, the semiconductor device may include a first gate structure GS1, a second gate structure GS2, first supports SP1, second supports SP2, or an isolation structure IS′, or a combination thereof. The isolation structure IS' may be located between the first gate structure GS1 and the second gate structure GS2. The isolation structure IS' may include first protrusions PR1 protruding between the first supports SP, include second protrusions PR2 protruding between the second supports SP2, or include the first protrusions PR1 and the second protrusions PR2.

The isolation structure IS' may further include first concave portions E1 located in a line part Ln, further include second concave portions E2, or include the first concave portions E1 and the second concave portion E1. The first concave portions E1 may be located between the first protrusions PR1 and the second concave portions E2 may be located between the second protrusions PR2. The first concave portions E1 may be located to correspond to first supports SP11. As an example, the first concave portions E1 may be located to correspond to first protruding patterns PP1 of the first supports SP11. A distance between the isolation structure IS' and the first supports SP11 may be secured through the first concave portions E1. The second concave portions E2 may be located to correspond to second supports SP21. As an example, the second concave portions E2 may be located to correspond to second protruding patterns PP2 of the second supports SP21. A distance between the isolation structure IS' and the second supports SP21 may be secured through the second concave portions E2. The first concave portions E1 may each have a shape such as a circle, an ellipse, a rectangle, or a polygon. The second concave portions E2 may have shapes similar to or different from those of the first concave portions E1.

The first supports SP11 may each include a first body pattern BP1 and the first protruding pattern PP1. The first protruding pattern PP1 may be located between the first protrusions PR1 and may be spaced apart from the first concave portion E1. Alternatively, the first protruding pattern PP1 may have a narrower width than the first concave portion E1, and the first protruding pattern PP1 may extend into the first concave portion E1. In the second direction II, the first body pattern BP1 may have a first length L1 and the first protrusion pattern PP1 may have a second length L2. The first length L1 and the second length L2 may be substantially the same as or different from each other. As an example, the second length L2 may be greater than the first length L1.

The second supports SP21 may each include a second body pattern BP2 and a second protruding pattern PP2. The second protruding pattern PP2 may be located between the second protrusions PR2 and may be spaced apart from the second concave portion E2. Alternatively, the second protruding pattern PP2 may have a narrower width than the second concave portion E2, and the second protruding pattern PP2 may extend into the second concave portion E2. The second supports SP21 may have shapes similar to or different from those of the first supports SP11.

According to the structure described above, even though the isolation structures IS and IS' of the semiconductor device each include the protrusions PR1 and PR2, distances between the isolation structures IS and IS' and the supports SP1 and SP2 may be secured by the protruding patterns PP1 and PP2. Distances between the isolation structure IS' and the supports SP1 and SP2 may be secured by the concave portions E1 and E2. By asymmetrically arranging the first supports SP1 and the second supports SP2, it is possible to improve structural stability of the semiconductor device without reducing the degree of integration of the semiconductor device. It is also possible to improve the reliability of the semiconductor device.

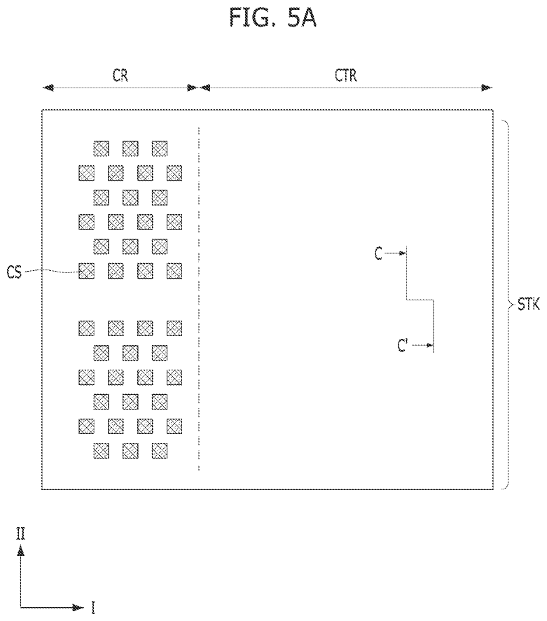

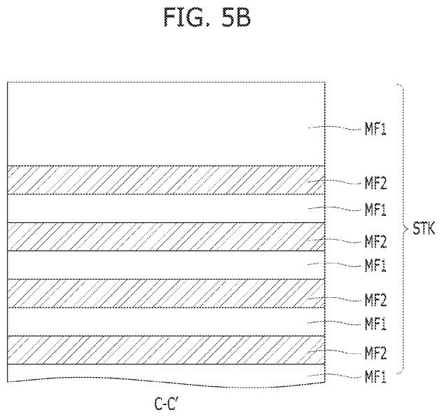

FIGS. 5A, 6A, 7A, 8A, 9A, 10A, and 11A and FIGS. 5B, 6B, 7B, 8B, 9B, 10B, and 11B are diagrams for describing a manufacturing method of a semiconductor device in accordance with an embodiment. FIGS. 5B, 6B, 7B, 8B, 9B, 10B, and 11B may be cross-sectional views taken along lines C-C′ of FIGS. 5A, 6A, 7A, 8A, 9A, 10A, and 11A, respectively. Hereinafter, the content overlapping with the previously described content will be omitted.

Referring to FIG. 5A and FIG. 5B, a stack structure STK may be formed. The stack structure STK may be formed on a lower structure such as a peripheral circuit and a source structure. The stack structure STK may include first material layers MF1 and second material layers MF2 that are alternately stacked. The second material layers MF2 may each include a material having a high etching selectivity with respect to the first material layers MF1. For example, the first material layers MF1 may each include an insulating material such as an oxide, and the second material layers MF2 may each include a sacrificial material such as a nitride. As another example, the first material layers MF1 may each include an insulating material such as an oxide, and the second material layers MF2 may each include a conductive material such as polysilicon, tungsten, or molybdenum. The stack structure STK may include a cell region CR and a contact region CTR. Subsequently, channel structures CS may be formed in the cell region CR of the stack structure STK.

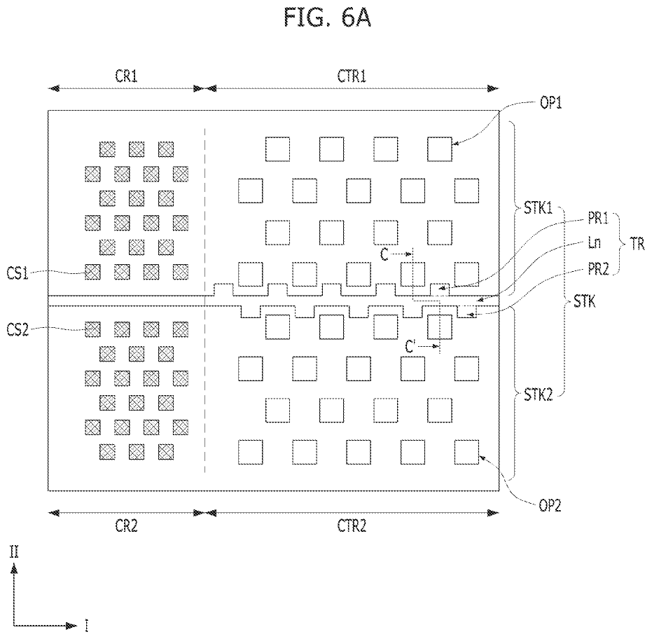

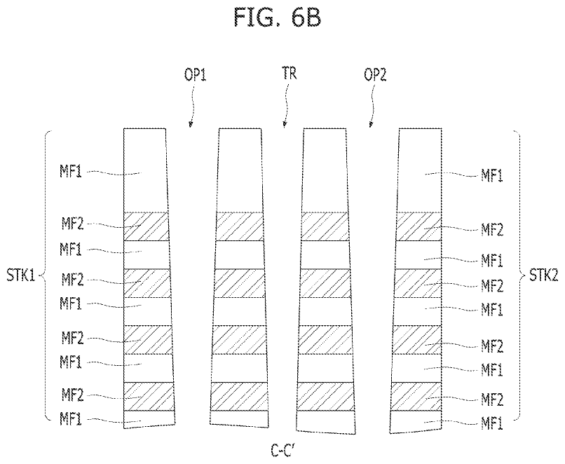

Referring to FIG. 6A and FIG. 6B, a trench TR may be formed in the stack structure STK. The trench TR may pass through the contact region CTR of the stack structure STK, and extend into the cell region CR. By the trench TR, the contact region CTR may be separated into a first contact region CTR1 and a second contact region CTR2 and the cell region CR may be separated into a first cell region CR1 and a second cell region CR2. The stack structure STK may be separated into a first stack structure STK1 and a second stack structure STK2 by the trench TR. The first stack structure STK1 may include the first cell region CR1 and the first contact region CTR1 adjacent to each other in the first direction I. The second stack structure STK2 may include the second cell region CR2 and the second contact region CTR2 adjacent to each other in the first direction I.

The trench TR may extend in the first direction I, and have a slit shape. Based on the trench TR, the channel structures CS may be divided into first channel structures CS1 and second channel structures CS2. The first channel structures CS1 may be located in the first cell region CR1 of the first stack structure STK1, and the second channel structures CS2 may be located in the second cell region CR2 of the second stack structure STK2. The first channel structures CS1 may be located on one side of the trench TR, and the second channel structures CS2 may be located on the other side of the trench TR. The first channel structures CS1 and the second channel structures CS2 may be arranged symmetrically or asymmetrically with the trench TR interposed therebetween.

The trench TR may include a line part Ln, at least one first protrusion PR1, or at least one second protrusion PR2, or a combination thereof. In the plane defined by the first direction I and the second direction II, the line part Ln may extend in the first direction I. The first protrusion PR1 and the second protrusion PR2 may protrude in the second direction II from the line part Ln. As an example, the first protrusion PR1 may protrude from the line part Ln toward the first stack structure STK1, and the second protrusion PR2 may protrude from the line part Ln toward the second stack structure STK2. Although not illustrated in this drawing, the trench TR may also include third protrusions protruding between the first channel structures CS1 or between the second channel structures CS2.

One or more first openings OP1 may be formed in the stack structure STK. The first openings OP1 may pass through the contact region CTR of the stack structure STK, and pass through the first contact region CTR1 of the first stack structure STK1. First openings OP1 adjacent to the trench TR among the first openings OP11 may be located between the first protrusions PR1. The first protrusions PR1 may protrude between the first openings OP1 from the line part Ln.

One or more second openings OP2 may be formed in the stack structure STK. The second openings OP2 may pass through the contact region CTR of the stack structure STK, and pass through the second contact region CTR2 of the second stack structure STK2. Second openings OP2 adjacent to the trench TR among the second openings OP2 may be located between the second protrusions PR2. The second protrusions PR2 may protrude between the second openings OP2 from the line part Ln.

The first openings OP1 may be located on one side of the trench TR, and the second openings OP2 may be located on the other side of the trench TR. The first openings OP1 and the second openings OP2 may be asymmetrically arranged in the plane defined by the first direction I and the second direction II. As an example, the first openings OP1 and the second openings OP2 may be formed to be asymmetrically arranged with the trench TR interposed therebetween. The first openings OP1 and the second openings OP2 may also be symmetrically arranged.

The trench TR, the first openings OP1, and the second openings OP2 may be formed substantially simultaneously or separately. As an example, when the trench TR is formed, the first openings OP1 and the second openings OP2 may be formed. When the trench TR, the first openings OP1, and the second openings OP2, which each have a high aspect ratio, are formed at the same time, the stack structure STK may be bent. When the trench TR includes only the line part Ln, there is a relatively high possibility that the stack structure STK is bent between the first openings OP1 or between the second openings OP2. Therefore, by placing the first protrusions PR1 between the first openings OP1 and placing the second protrusions PR2 between the second openings OP2, it is possible to reduce, prevent, or minimize bending of the stack structure STK.

The shape of each of the first openings OP1 or the trench TR may be set in consideration of a distance between the first protrusions PR1 and the first openings OP1. The first openings OP1 may have substantially the same shape or different shapes. As an example, first openings OP1 located close to the first trench TR1 among the first openings OP1 may each include a first protruding pattern protruding between the first protrusions PR1 and having a relatively narrow width. Similarly, second openings OP2 located close to the second protrusions PR2 among the second openings OP2 may each include a second protruding pattern protruding between the second protrusions PR2 and having a relatively narrow width. As an example, the first openings OP1 and the second openings OP2 may each have a “T” shape. The trench TR may also include concave portions located to correspond to the protruding patterns so as to secure a distance between the protruding patterns and the trench TR.

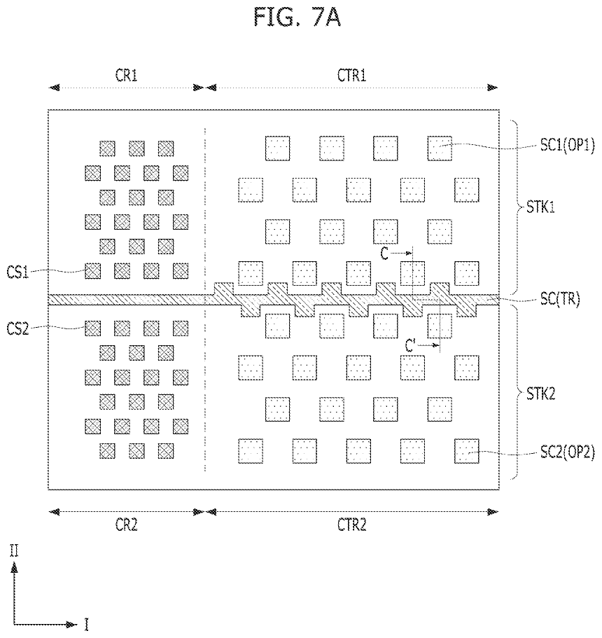

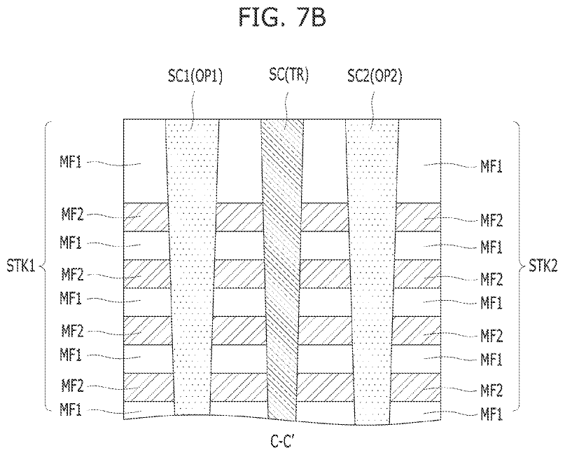

Referring to FIG. 7A and FIG. 7B, a sacrificial layer SC may be formed in the trench TR. First sacrificial layers SC1 may be formed in the first openings OP1. Second sacrificial layers SC2 may be formed in the second openings OP2. When the sacrificial layer SC is formed, the first sacrificial layers SC1 and the second sacrificial layers SC2 may be formed. As an example, a sacrificial material may be formed to fill the trench TR, the first openings OP1, and the second openings OP2. Subsequently, the sacrificial layer SC, the first sacrificial layers SC1, and the second sacrificial layers SC2 may be formed by planarizing the sacrificial material until upper surfaces of the first stack structure STK1 and the second stack structure STK2 are exposed. The sacrificial layer SC, the first sacrificial layers SC1, and the second sacrificial layers SC2 may each include a material having a high etching selectivity with respect to the first material layers MF1 and the second material layers MF2. As an example, the sacrificial layer SC, the first sacrificial layers SC1, and the second sacrificial layers SC2 may each include a metal such as tungsten.

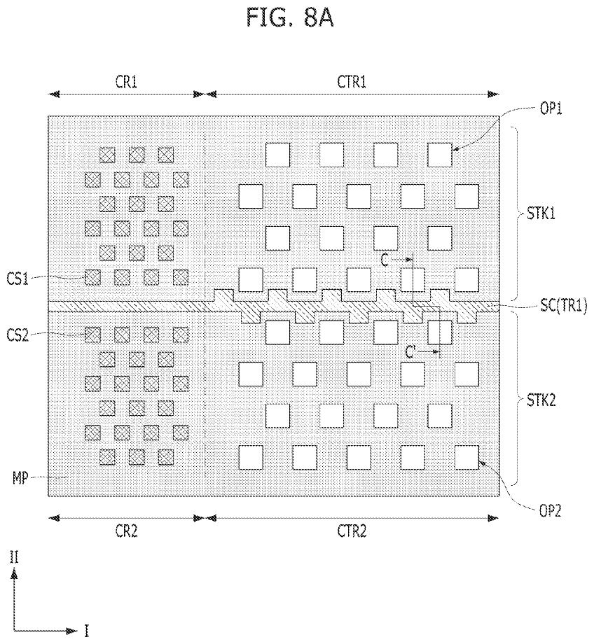

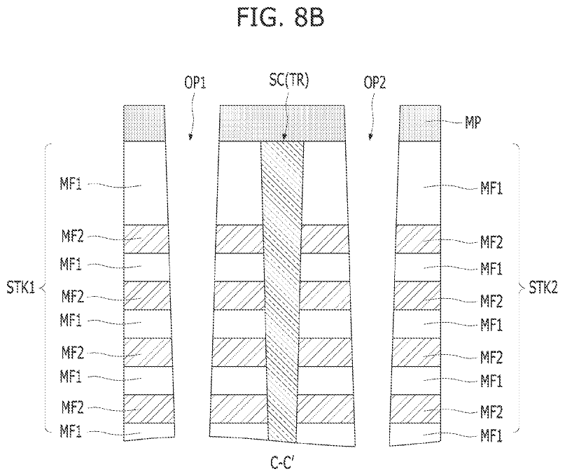

Referring to FIG. 8A and FIG. 8B, the first openings OP1 may be reopened by removing the first sacrificial layers SC1. The second openings OP2 may be reopened by removing the second sacrificial layers SC2. When the first sacrificial layers SC1 are removed, the second sacrificial layers SC2 may be removed. As an example, after a mask pattern MP that covers the first cell region CR1, the second cell region CR2, and the sacrificial layer SC and exposes the first sacrificial layers SC1 and the second sacrificial layers SC2 is formed, the first sacrificial layers SC1 and the second sacrificial layers SC2 may be selectively etched using the mask pattern MP as an etch barrier. Subsequently, the mask pattern MP may be removed.

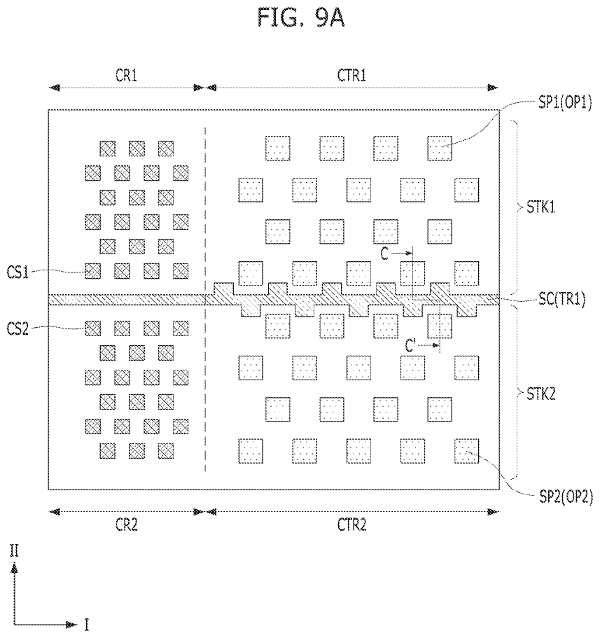

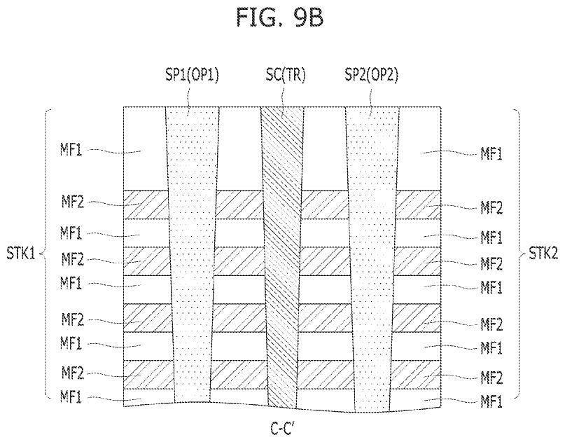

Referring to FIG. 9A and FIG. 9B, first supports SP1 may be formed in the first openings OP1. The first supports SP1 may pass through the first contact region CTR1 of the first stack structure STK1. Second supports SP2 may be formed in the second openings OP2. The second supports SP2 may pass through the second contact region CTR2 of the second stack structure STK2. When the first supports SP1 are formed, the second supports SP2 may be formed. As an example, after a support material is formed on the first stack structure STK1 and the second stack structure SKT2 to fill the first openings OP1 and the second openings OP2, the first supports SP1 and the second supports SP2 may be formed by planarizing the support material until the upper surfaces of the first stack structure STK1 and the second stack structure SKT2 are exposed. The first support SP1 and the second support SP2 may each include an oxide, a nitride, or a metal, or a combination thereof.

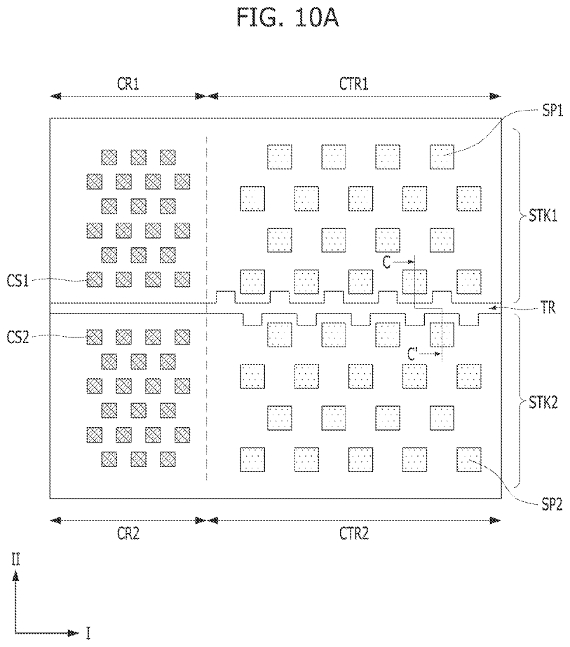

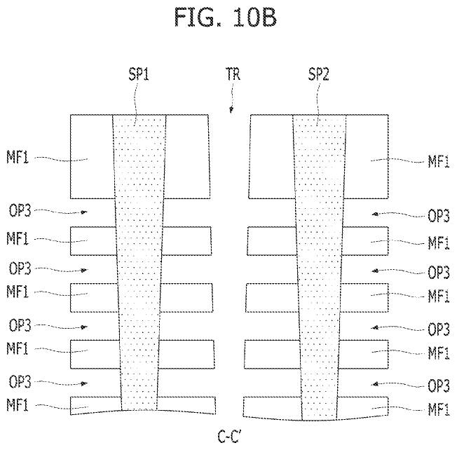

Referring to FIG. 10A and FIG. 10B, the sacrificial layer SC may be removed. The trench TR may be reopened by selectively etching the sacrificial layer SC. Subsequently, the second material layers MF2 may be removed. Third openings OP3 may be formed by selectively etching the second material layers MF2 through the trench TR. In such a case, the first material layers MF1 may be supported by the first supports SP1 and the second supports SP2.

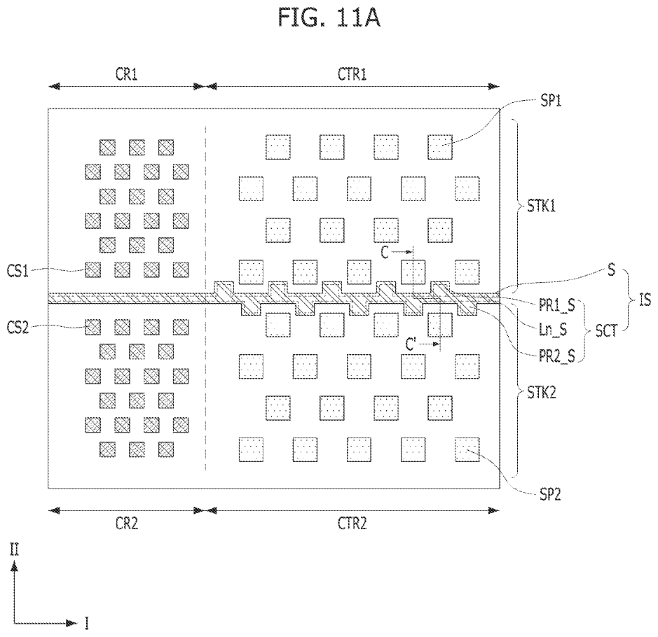

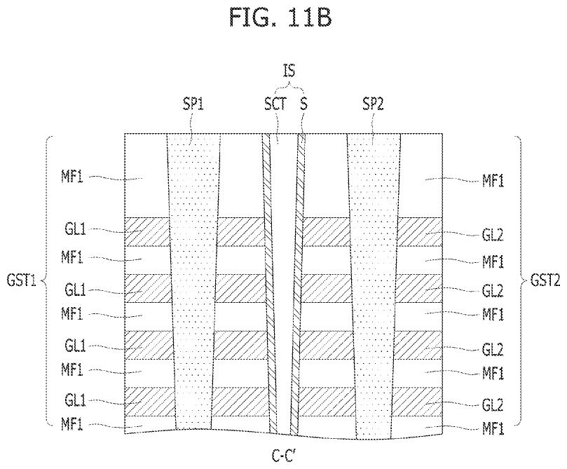

Referring to FIG. 11A and FIG. 11B, first gate lines GL1 and second gate lines GL2 may be formed in the third openings OP3. Through this, a first gate structure GS1 including the stacked first gate lines GL1 and a second gate structure GS2 including the stacked second gate lines GL2 may be formed. The first gate lines GL1 and the second gate lines GL2 may each include a conductive material such as polysilicon, tungsten, molybdenum, or metal.

When the first material layers MF1 each include an insulating material and the second material layers MF2 each include a conductive material, the third openings OP3 might not be formed. In such a case, the second material layers MF2 may be used as gate lines. If necessary, it is also possible to perform a silicidation process for reducing the resistance of the second material layers MF2.

Subsequently, an isolation structure IS may be formed in the trench TR. The isolation structure IS may have a structure corresponding to the trench TR. The isolation structure IS may be used to electrically isolate the first gate structure GS1 and the second gate structure GS2. The isolation structure IS may be formed by filling the trench TR with an insulating material.

Alternatively, the isolation structure IS may include a contact structure electrically connected to a lower structure such as a source structure. After an insulating spacer S is formed on sidewalls of the trench TR, a source contact structure SCT electrically connected to the source structure may be formed. The insulating spacer S may be formed along the inner surface of the trench TR. Because the source contact structure SCT is formed in the insulating spacer S, the shape of the source contact structure SCT may vary depending on the shape, thickness, and the like of the insulating spacer S. As an example, the insulating spacer S may partially fill the first protrusions PR1, the second protrusions PR2, and the line part Ln of the trench TR, and the source contact structure SCT may fill the remaining region of the trench TR. In such a case, the source contact structure SCT may include a line part Ln_S, first protrusions PR1_S, and second protrusions PR2_S like the trench TR. As an example, the insulating spacer S may completely fill the first protrusions PR1 and the second protrusions PR2 of the trench TR, and the source contact structure SCT may include only the line part Ln_S without any protrusion.

According to the manufacturing method described above, the trench TR including the first protrusions PR1 and the second protrusions PR2 may be formed. Accordingly, even though the trench TR, the first openings OP1 and the second openings OP2, which each have a high aspect ratio, are formed at the same time, it is possible to reduce, prevent, or minimize bending of the stack structure STK. It is also possible to secure a distance between the trench TR and the openings OP1 and OP2 by forming the first openings OP1 and the second openings OP2 including protruding patterns or forming the isolation structure IS including the concave portions E1 and E2. Consequently, it is possible to reduce defects in the manufacturing process and reduce the manufacturing cost.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and/or changes for the embodiments may be made by those skilled in the art, to which the present disclosure pertains, without departing from the technical idea of the present disclosure defined in the following claims, and it should be construed that these substitutions, modifications, and/or changes belong to the scope of the present disclosure.

What is claimed is:

1. A semiconductor device comprising:
a first gate structure including first interlayer dielectric layers and first gate lines that are alternately stacked;
a plurality of first supports passing through the first gate structure;
a second gate structure including second interlayer dielectric layers and second gate lines that are alternately stacked;
a plurality of second supports passing through the second gate structure; and
an isolation structure disposed between the first gate structure and the second gate structure, the isolation structure including one or more first protrusions protruding between the first supports and one or more second protrusions protruding between the second supports.

2. The semiconductor device of claim 1, wherein each of the plurality of first supports includes a first protruding pattern protruding between the first protrusions.

3. The semiconductor device of claim 1, wherein each of the plurality of second supports includes a second protruding pattern protruding between the second protrusions.

4. The semiconductor device of claim 1, wherein:
The first gate structure includes a first cell region where a first channel structure is disposed and a first contact region where the first supports are disposed; and
the second gate structure includes a second cell region where a second channel structure is disposed and a second contact region where the second supports are disposed.

5. The semiconductor device of claim 4, wherein:
the isolation structure is interposed between the first channel structure and the second channel structure; and
the first channel structure and the second channel structure are symmetrically arranged with the isolation structure interposed therebetween.

6. The semiconductor device of claim 4, wherein:
the isolation structure is interposed between the first channel structure and the second channel structure; and
the first channel structure and the second channel structure are asymmetrically arranged with the isolation structure interposed therebetween.

7. The semiconductor device of claim 4, wherein:
the isolation structure is interposed between the first supports and the second supports; and
the first supports and the second supports are asymmetrically arranged with the isolation structure interposed therebetween.

8. The semiconductor device of claim 1, wherein a lower part of the first support has a narrower width than an upper part of the first support.

9. A semiconductor device comprising:
a first gate structure including a first cell region and a first contact region;
a second gate structure including a second cell region and a second contact region;
an isolation structure disposed between the first gate structure and the second gate structure, the isolation structure including a first protrusion protruding toward the first gate structure and a second protrusion protruding toward the second gate structure;
a first support passing through the first contact region; and
a second support passing through the second contact region, the second support arranged asymmetrically with the first support with the isolation structure interposed between the second support and the first support.

10. The semiconductor device of claim 9, further comprising:
a first channel structure passing through the first cell region; and
a second channel structure passing through the second cell region, the second channel structure arranged symmetrically with the first channel structure with the isolation structure interposed between the second channel structure and the first channel structure.

11. The semiconductor device of claim 9, further comprising:
a first channel structure passing through the first cell region; and
a second channel structure passing through the second cell region, the second channel structure arranged asymmetrically with the first channel structure with the isolation structure interposed between the second channel structure and the first channel structure.

12. The semiconductor device of claim 9, wherein a lower part of the first support has a narrower width than an upper part of the first support.

13. The semiconductor device of claim 9, wherein:
the first gate structure includes first interlayer dielectric layers and first gate lines that are alternately stacked; and
the second gate structure includes second interlayer dielectric layers and second gate lines that are alternately stacked.

14. A manufacturing method of a semiconductor device, the manufacturing method comprising:
forming a stack structure including first material layers and second material layers that are alternately stacked;
forming a trench separating the stack structure into a first stack structure and a second stack structure, the trench including a protrusion;
forming a first opening passing through the first stack structure;
forming a second opening passing through the second stack structure;
forming an isolation structure in the trench; and
forming supports in the first opening and the second opening.

15. The manufacturing method of claim 14, wherein the first opening and the second opening are formed when the trench is formed.

16. The manufacturing method of claim 14, wherein the first opening is formed to be arranged asymmetrically with the second opening with the trench interposed between the first opening and the second opening.

17. The manufacturing method of claim 14, wherein:
the first stack structure includes a first cell region and a first contact region;
the second stack structure includes a second cell region and a second contact region;
the first opening is located in the first contact region; and
the second opening is located in the second contact region.

18. The manufacturing method of claim 17, further comprising:
forming a first channel structure in the first cell region; and
forming a second channel structure in the second cell region.

19. The manufacturing method of claim 18, wherein the first channel structure and the second channel structure are symmetrically arranged with the trench interposed between the first channel structure and the second channel structure.

20. A manufacturing method of a semiconductor device, the manufacturing method comprising:
forming a stack structure including a cell region and a contact region;
forming channel structures passing through the cell region of the stack structure;
forming supports passing through the contact region of the stack structure; and
forming an isolation structure passing through the contact region of the stack structure, the isolation structure including protrusions protruding between the supports.

21. The manufacturing method of claim 20, wherein each of the supports includes a protruding pattern protruding between the protrusions.

22. The manufacturing method of claim 20, wherein:
the supports include first supports located on one side of the isolation structure and second supports located on the other side of the isolation structure; and
the protrusions include first protrusions protruding between the first supports and second protrusions protruding between the second supports.

23. The manufacturing method of claim 22, wherein the first protrusions and the second protrusions are asymmetrically arranged.

24. The manufacturing method of claim 22, wherein the first supports and the second supports are asymmetrically arranged.

25. The manufacturing method of claim 20, wherein:
the channel structures include first channel structures located on one side of the isolation structure and second channel structures located on the other side of the isolation structure; and
the first channel structures and the second channel structures are symmetrically arranged.

26. The manufacturing method of claim 20, wherein forming of the supports comprises:
forming openings passing through the contact region of the stack structure; and
forming the supports in the openings.

27. The manufacturing method of claim 26, wherein forming of the isolation structure comprises:
forming a trench passing through the contact region of the stack structure and including protrusions protruding between the openings; and
forming the isolation structure in the trench.

28. The manufacturing method of claim 27, wherein the trench is formed when the openings are formed.
